(19) United States
(12) Patent Application Publication
(10) Pub. No.: US 2007/0170544 A1
(43) Pub. Date: Jul. 26, 2007

(54) SEMICONDUCTOR DEVICE WITH METAL FUSES

(75) Inventor: Hidetoshi Koike, Yokohama-shi (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignee: KABUSHIKI KAISHA TOSHIBA, Tokyo (JP)

(21) Appl. No.: 11/624,809

(22) Filed: Jan. 19, 2007

(30) Foreign Application Priority Data
Jan. 20, 2006 (JP) 2006-012279
Dec. 15, 2006 (JP) 2006-338719

(51) Int. Cl. H01L 29/00

(52) U.S. Cl. 257/529

(57) ABSTRACT

A trench dummy element isolating region is formed in the fuse region of a semiconductor substrate. In the semiconductor substrate, a plurality of dummy element regions is formed so as to be enclosed by the trench dummy element isolating region. The occupancy rate of the plurality of dummy element regions in the fuse region is equal to or larger than a specific value. On the semiconductor substrate including the dummy element isolating region and dummy element regions, a plurality of metal fuses composed of multilayer metal wiring lines are formed via an interlayer insulating film. The plurality of dummy element regions are formed only below at least a part of the plurality of metal fuses.

### CROSS-REFERENCE TO RELATED APPLICATIONS

This application is based upon and claims the benefit of priority from prior Japanese Patent Applications No. 2006-012279, filed Jan. 20, 2006; and No. 2006-338719, filed Dec. 15, 2006, the entire contents of both of which are incorporated herein by reference.

### BACKGROUND OF THE INVENTION

1. Field of the Invention

This invention relates to a semiconductor device with fuses, and more particularly to the arrangement of a dummy element isolation region below the fuse region, which is used in, for example, a memory LSI or an LSI with a memory.

2. Description of the Related Art

As semiconductor memories have been getting higher in density and larger in capacity, it is becoming impossible to request a whole chip to have no defect. Therefore, it is common practice for a memory LSI and an LSI with a memory to use a redundancy configuration which includes a defect remedy circuit. When a spare cell is used in place of a defective cell, the address of the defective cell is generally stored by a tester and then fuses composed of a multilayer metal wiring layer, such as Cu or Al, are blown (or laser-blown) by the irradiation of laser light, thereby selecting a spare cell in place of the defective cell. To avoid a decrease in the yield due to the recent tendency for LSIs to have higher capacity, the number of fuses is extremely large and therefore the area of the fuse region increases.

Generally, a dummy element isolating region is provided in a wide element forming region in a semiconductor substrate, thereby preventing dishing due to chemical mechanical polishing (CMP). Dishing is a phenomenon where the surface of an insulating layer or the like is ground into a dish-like film, with the result that the film thickness of the insulating film and others gets thinner.

In the prior art, to avoid the breaking of the semiconductor substrate in laser-blowing fuses, a wide element isolating region is provided below the fuse region. As a result, at the time of CMP after the formation of the element isolating region, dishing takes place in the element isolating region below the fuse region. When a multilayer metal wiring layer for fuses is formed on the dishing occurring region, the metal wiring lines at the bottom layer are not flattened sufficiently, producing the residual Cu, which causes a problem: the short-circuit (or metal short) between fuses takes place. To avoid this problem, the fuse region is divided into a plurality of sub-regions and a dummy element isolating regions is provided between sub-regions, leading to an increase in the chip area.

Jpn. Pat. Appln. KOKAI Publication No. 2004-319566 has disclosed a method of forming an element isolating region with a trench dummy pattern on a semiconductor substrate, covering a dummy pattern below a fuse element forming region with a protective film for preventing the surface of the substrate from being turned into salicide before a salicide process to be carried out later, and then forming fuse elements.

### BRIEF SUMMARY OF THE INVENTION

According to an aspect of the invention, there is provided a semiconductor device with metal fuses comprising: a semiconductor substrate which has a fuse region; a trench dummy element isolating region which is formed in the semiconductor substrate; a plurality of dummy element regions which is formed in the semiconductor substrate so as to be enclosed by the trench dummy element isolating region and whose occupancy rate in the fuse region is equal to or larger than a specific value; and a plurality of metal fuses which is composed of multilayer metal wiring lines and which is formed via an interlayer insulating film in the fuse region on the semiconductor substrate including the trench dummy element isolating region and dummy element regions, wherein said plurality of dummy element regions is formed only below at least a part of said plurality of metal fuses.

### BRIEF DESCRIPTION OF THE SEVERAL VIEWS OF THE DRAWING

FIG. 1 is a plan view of an LSI according to a first embodiment of the present invention;

FIG. 2 is a plan view schematically showing a pattern of the bottom-layer metal wiring and contact section in the LSI of FIG. 1;

FIG. 3 is a plan view schematically showing a pattern of a trench dummy element isolating region provided below the 4-layer metal wiring in the LSI of FIG. 1;

FIG. 4 is a sectional view showing a first step in an LSI manufacturing method shown in FIGS. 1 to 3;

FIG. 5 is a sectional view to help explain a step following FIG. 4;

FIG. 6 is a sectional view to help explain a step following FIG. 5;

FIG. 7 is a sectional view to help explain a step following FIG. 6;

FIG. 8 is a sectional view to help explain a step following FIG. 7;

FIG. 9 is a sectional view to help explain a step following FIG. 8;

FIG. 10 is a plan view of an LSI according to a second embodiment of the invention;

FIG. 11 is a plan view of an LSI according to a third embodiment of the invention; and

FIG. 12 is a sectional view of an LSI according to a fourth embodiment of the invention.

### DETAILED DESCRIPTION OF THE INVENTION

Hereinafter, referring to the accompanying drawings, embodiments of the invention will be explained. In explanation, the parts common to all the drawings are assigned common reference numerals.

### First Embodiment

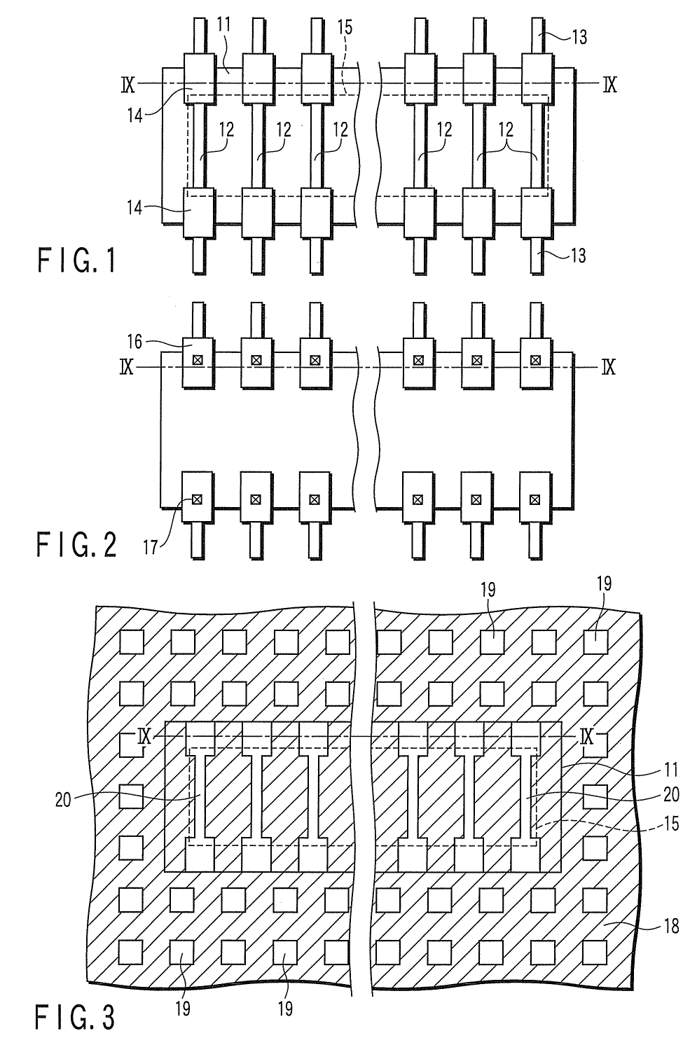

FIG. 1 schematically shows a planar layout of a fuse region composed of the top-layer metal wiring and its vicinity in a semiconductor integrated circuit (LSI) with 4-layer wiring composed of such metal as Cu according to a first embodiment of the invention. In FIG. 1, numeral 11 indicates a fuse region, numeral 12 a metal fuse, numeral 13 a fuse control circuit wiring line, numeral 14 a junction of the metal fuse and the fuse control circuit wiring line, and numeral 15 a fuse opening.

FIG. 2 schematically shows a pattern of the bottom-layer metal wiring and contact section in the LSI of FIG. 1. Numeral 16 indicates a metal wiring line and numeral 17 indicates a contact section connecting with the top-layer metal wiring.

FIG. 3 schematically shows a pattern of a trench dummy element isolating region provided below the metal wiring in the LSI of FIG. 1. In FIG. 3, the area shaded with upward sloping lines is a dummy element isolating region 18. Numeral 19 indicates a plurality of dummy element regions formed so as to be enclosed by the dummy element isolating region 18 in the area around the fuse region 11. Numeral 20 indicates a plurality of dummy element regions formed so as to be enclosed by the dummy element isolating region 18 in the fuse region 11. Each of the dummy element regions 19, 20 is a region where the surface of the original substrate enclosed by the dummy element isolating region 18 is exposed. Depending on the mode of the manufacturing process, the surface of each of the dummy element isolating regions 19, 20 may or may not be turned into salicide.

FIG. 9 schematically shows a cross-sectional structure taken along line IX-IX in FIGS. 1 to 3, focusing on the fuse region 11 in the LSI of FIG. 1. FIG. 9 shows a case where the surface of the dummy element region 20 is not turned into salicide. In FIG. 9, numeral 21 indicates a semiconductor substrate (silicon substrate), numeral 14 a junction of a metal fuse and a fuse control circuit wiring line, and numeral 23 a passivation film formed on the surface. Numeral 18 indicates a trench dummy element isolating region formed in the semiconductor substrate 21 below the fuse region 11. A plurality of dummy element regions 20 are formed in the substrate 21 so as to be enclosed by the dummy element isolating region 18. The plurality of dummy element regions 20 are formed so that their occupation rate in the fuse region 11 may be equal to or larger than a specified value. The plurality of dummy element regions 20 are formed below at least a part of the plurality of metal fuses 12. However, the plurality of dummy element regions 20 may be formed below all of the plurality of metal fuses 12.

In the first embodiment, as shown in FIGS. 1 to 3, each of the plurality of dummy element regions 20 is formed so as to have the same planar shape as that of the corresponding one of the plurality of metal fuses above in the same plane position as that of the metal fuse.

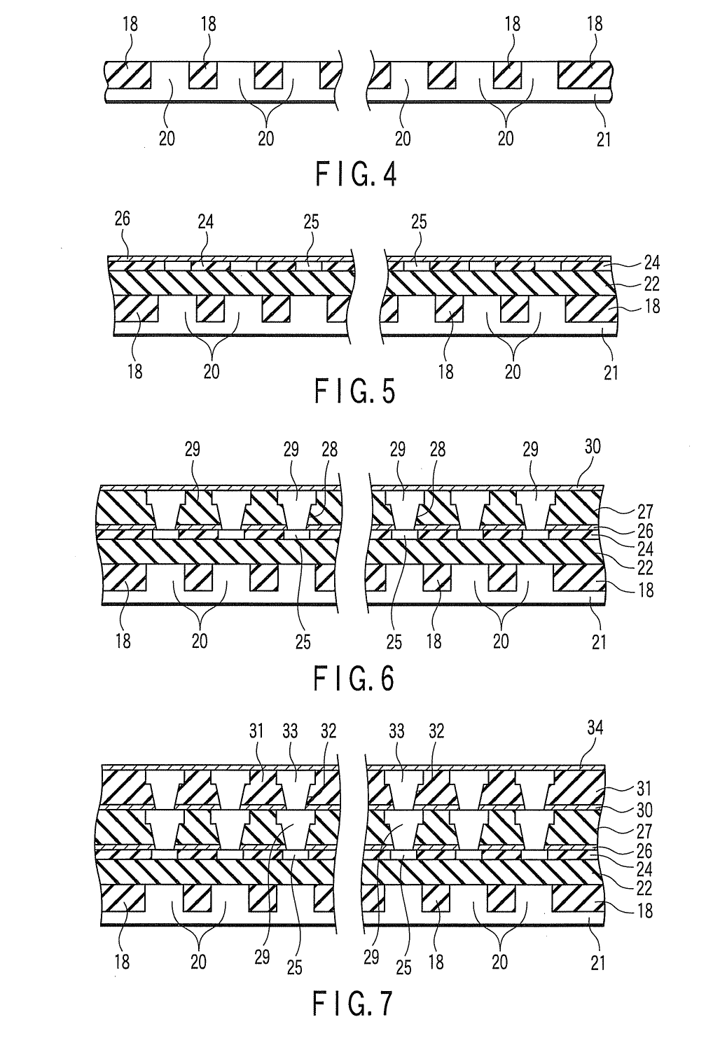

FIGS. 4 to 9 schematically show a cross-sectional structure taken along line IX-IX in FIGS. 1 to 3 in the LSI manufacturing process shown in FIGS. 1 to 3.

First, as shown in FIG. 4, a trench element isolating region 18 and dummy element regions 20 are formed in a silicon substrate 21 by STI (Shallow Trench Isolation) techniques. Then, diffusion layers and polysilicon gates (not shown) are formed.

Next, as shown in FIG. 5, a first interlayer insulating film 22, such as a BPSG film, is deposited. The first interlayer insulating film 22 is flattened using CMP techniques. Thereafter, using photolithographic techniques, first contact holes are made in the interlayer insulating film 22. First tungsten is embedded in the contact holes. Then, a second interlayer insulating film 24, such as an SiO₂ film, is deposited. Using photolithographic techniques, first wiring grooves of a specific shape are made in the second interlayer insulating film 24. Thereafter, a first Cu layer 25 is deposited all over the surface. Using CMP techniques, the first Cu layer 25 is flattened. Then, to prevent Cu from oxidizing and from diffusing, a barrier film 26, such as a thin SiN film, is deposited. The above steps constitute a Cu wiring single damascene process.

Next, as shown in FIG. 6, a third interlayer insulating film 27, such as an SiO₂ film, is deposited. Using photolithographic techniques, second contact holes 28 are made in the third interlayer insulating film 27. Furthermore, using photolithographic techniques, second wiring grooves of a specific shape are made in the third interlayer insulating film 27. Thereafter, a second Cu layer 29 is deposited all over the surface. Using CMP techniques, the second Cu layer 29 is flattened. Then, to prevent Cu from oxidizing and from diffusing, a barrier film 30, such as a thin SiN film, is deposited. The above steps constitute a Cu wiring dual damascene process.

Next, as shown in FIG. 7, a fourth interlayer insulating film 31, such as an SiO₂ film, is deposited. Using photolithographic techniques, third contact holes 32 are made in the fourth interlayer insulating film 31. Furthermore, using photolithographic techniques, third wiring grooves of a specific shape are made in the fourth interlayer insulating film 31. Thereafter, a third Cu layer 33 is deposited all over the surface. Using CMP techniques, the third Cu layer 33 is flattened. Then, to prevent Cu from oxidizing and from diffusing, a barrier film 34, such as a thin SiN film, is deposited.

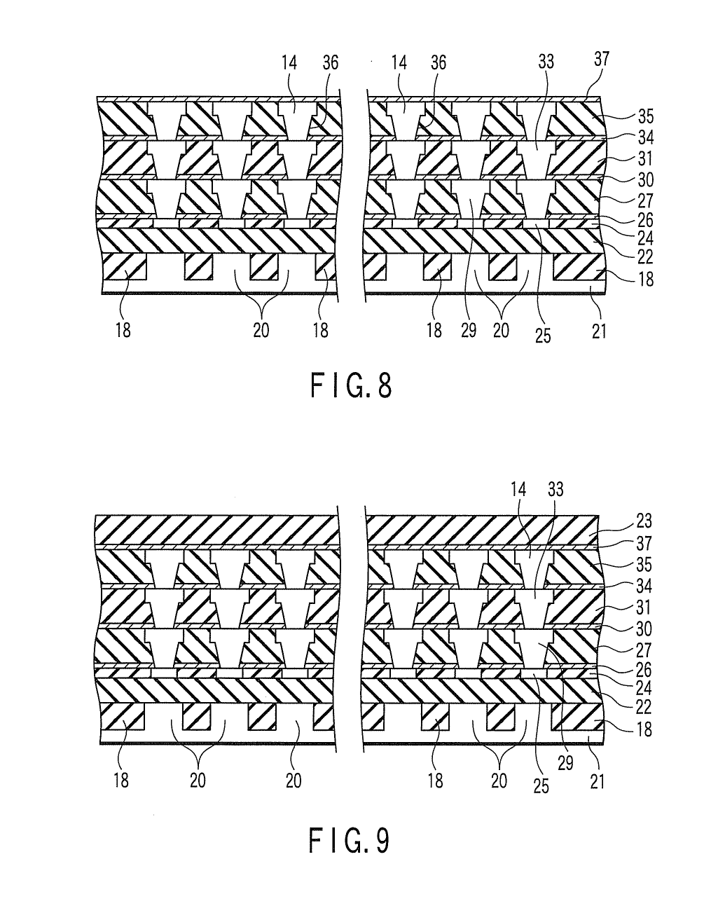

Next, as shown in FIG. 8, a fifth interlayer insulating film 35, such as an SiO₂ film, is deposited. Using photolithographic techniques, fourth contact holes 36 are made in the fifth interlayer insulating film 35. Furthermore, using photolithographic techniques, fourth wiring grooves of a specific shape are made in the fifth interlayer insulating film 35. Thereafter, a fourth Cu layer is deposited all over the surface. Using CMP techniques, the fourth Cu layer is flattened to form metal fuses and the junctions 14 of the metal fuses and the metal fuse control circuit wiring lines. Then, to prevent Cu from oxidizing and from diffusing, a barrier film 37, such as a thin SiN film, is deposited.

Next, as shown in FIG. 9, a passivation film 23, such as a PSG film, is deposited. Using photolithographic techniques, the passivation film 23 is etched, thereby making fuse openings (not shown).

In the LSI of the first embodiment, as shown in FIG. 3, not only is the dummy element isolation regions 18 arranged in the wide element isolating region, but also the dummy element regions 20 are arranged below the fuse region 12. In this case, each dummy element region 20 is formed so as to extend to below the metal fuse 12 and fuse control circuit wiring line junction 14.

With the above configuration, no dishing takes place in embedding the element isolation insulating film in the element isolating grooves to form the dummy element isolating regions 18 as shown in FIG. 3. Therefore, as shown in FIG. 5, after the first interlayer insulating film 22 is deposited and then flattened by CMP techniques, the first Cu layer 25 is deposited and then flattened by CMP techniques. At this time, the first Cu layer 25 is flattened sufficiently. Accordingly, as shown in FIG. 2, since there is no residual Cu between the metal wiring lines 16, no short-circuiting takes place between metal fuses.

Furthermore, below the metal fuse (12 in FIG. 1), the dummy element region 20 is provided so as to have the same planar shape as that of the metal fuse in the same plane position as that of the metal fuse. In other words, each dummy element region 20 is formed so as to have the same planar shape as that of the corresponding one of the dummy element regions 20 above in the same plane position as that of the metal fuses 12. This causes the metal fuse to block laser light in laser-blowing the metal fuse 12, preventing the laser light from reaching the surface of the dummy element region 20 below the metal fuse, with the result that the dummy element region 20 will not break. Accordingly, there is no need to divide the fuse region 11 and provide dummy element isolating regions between the divided fuse regions to avoid dishing and therefore there is no increase in the chip area.

Since the surface is flattened so as to prevent dishing at the time of CMP, the total of the areas occupied by the dummy element regions 20 in the fuse area 11 is made so as to be 20% or more of the area of the fuse region 11. To flatten the surface more, the total of the areas occupied by the dummy element regions 20 in the fuse region 11 is made so as to be 20% or more of the area of the fuse region 11 and the area occupied by the dummy element region 20 in an arbitrary square region of 100 μm×100 μm in the fuse region 11 is made so as to be 2000 μm² or more.

### Second Embodiment

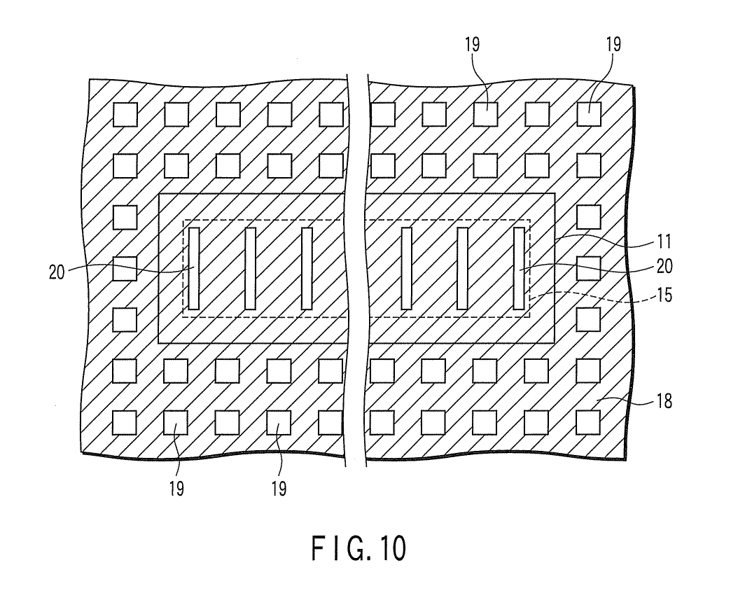

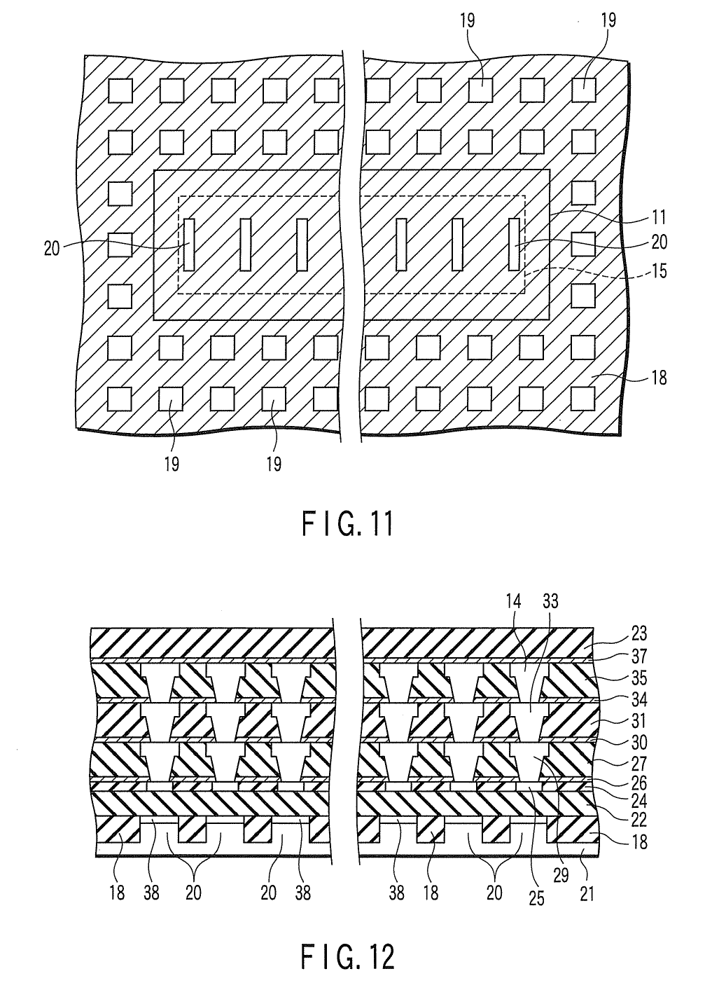

FIG. 10 schematically shows a pattern of a trench dummy element isolating region provided below the metal wiring in an LSI with 4-layer metal wiring according to a second embodiment of the invention. As in FIG. 3, numeral 15 indicates a fuse opening, numeral 18 a dummy element isolating region, numeral 19 a plurality of dummy element regions formed so as to be enclosed by the dummy element isolating region 18 in the region around the fuse region 11, and numeral 20 a plurality of dummy element regions formed so as to be enclosed by the dummy element isolating region 18 in the fuse region 11. Each of the dummy element regions 19, 20 is a region where the surface of the original substrate enclosed by the dummy element isolating region 18 is exposed.

The second embodiment differs from the first embodiment in that the dummy element region 20 is not formed below the junction 14 of the metal fuse and the fuse control circuit wiring line and the dummy element isolating region 18 is formed so as to be extended. Generally, as the area of the dummy element region 20 becomes larger, dishing is less liable to take place.

### Third Embodiment

FIG. 11 schematically shows a pattern of a trench dummy element isolating region provided below the metal wiring in an LSI with 4-layer metal wiring according to a third embodiment of the invention. As in FIG. 3, numeral 15 indicates a fuse opening, numeral 18 a dummy element isolating region, numeral 19 a plurality of dummy element regions formed so as to be enclosed by the dummy element isolating region 18 in the region around the fuse region 11, and numeral 20 a plurality of dummy element regions formed so as to be enclosed by the dummy element isolating region 18 in the fuse region 11. Each of the dummy element regions 19, 20 is a region where the surface of the original substrate enclosed by the dummy element isolating region 18 is exposed.

In the third embodiment, each dummy element region 20 below the fuse region 12 has a smaller planar shape than that of the corresponding metal fuse 12 above in the same plane position as that of the metal fuse 12. In other words, the dummy element region 20 is provided below the metal fuse so as to have a smaller planar shape than that of the metal fuse in the same plane position as that of the metal fuse.

Even with this configuration, since no dishing takes place while the dummy element isolating region 18 is being subjected to CMP, the first Cu layer 25 is flattened sufficiently as shown in FIG. 5, there is no residual Cu. Accordingly, a short circuit problem between metal fuses can be avoided. For the same reason as described above, when the metal fuse 12 is blown with laser, the dummy element region 20 below the metal fuse will not break. Accordingly, there is no need to divide the fuse region 11 and provide dummy element isolating regions between the divided fuse regions to avoid dishing and therefore there is no increase in the chip area.

### Fourth Embodiment

FIG. 12 schematically shows a cross-sectional structure of a fuse region 11 in an LSI with 4-layer metal wiring according to a fourth embodiment of the invention. The basic configuration is the same as that of the first embodiment of FIG. 9. The fourth embodiment differs from the first embodiment only in that the surface of the dummy element region 20 below the metal fuse is turned into salicide, thereby forming a salicide region 38.

In the fourth embodiment, the dummy element region 20 below the metal fuse may be formed so as to have the same planar shape as that of the corresponding metal fuse 12 above in the same plane position as that of the metal fuse as shown in FIG. 1. Alternatively, as in FIGS. 10 and 11, the dummy element region 20 may be formed so as to have a smaller planar shape than that of the corresponding metal fuse above in the same plane position as that of the metal fuse.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device with metal fuses comprising:
a semiconductor substrate which has a fuse region;
a trench dummy element isolating region which is formed in the semiconductor substrate;
a plurality of first dummy element regions which is formed in the semiconductor substrate, said plurality of first dummy element regions being enclosed by the trench dummy element isolating region and whose occupancy rate in the fuse region is equal to or larger than a specific value; and
a plurality of metal fuses which is composed of multilayer metal wiring lines and which is formed via an interlayer insulating film in the fuse region on the semiconductor substrate including the trench dummy element isolating region and first dummy element regions,
wherein said plurality of first dummy element regions is formed only below at least a part of said plurality of metal fuses.

2. The semiconductor device according to claim 1, wherein each of said plurality of first dummy element regions has the same planar shape as that of the corresponding one of the metal fuses above in the same plane position as that of the metal fuse.

3. The semiconductor device according to claim 1, wherein each of said plurality of first dummy element regions has a smaller planar shape than that of the corresponding one of the metal fuses above in the same plane position as that of the metal fuse.

4. The semiconductor device according to claim 1, wherein each of said plurality of first dummy element regions is formed to extend to below a fuse control circuit wiring line junction connecting with each of said plurality of metal fuses.

5. The semiconductor device according to claim 1, wherein the substrate surface of each of said plurality of first dummy element regions formed below each of said plurality of metal fuses is turned into salicide.

6. The semiconductor device according to claim 1, wherein the substrate surface of each of said plurality of dummy element regions formed below each of said plurality of metal fuses is not turned into salicide.

7. The semiconductor device according to claim 1, wherein the total of the areas occupied by the first dummy element regions in the fuse region is 20% or more of the area of the fuse region.

8. The semiconductor device according to claim 1, wherein the fuse region is provided in the trench dummy element region, a plurality of second dummy element regions being formed in the trench dummy element region.

9. A semiconductor device with metal fuses comprising:
a semiconductor substrate which has a fuse region;
a trench dummy element isolating region which is formed in the semiconductor substrate;
a plurality of first dummy element regions which is formed in the semiconductor substrate, said plurality of first dummy element regions being enclosed by the trench dummy element isolating region and whose occupancy rate in the fuse region is equal to or larger than a specific value; and
a plurality of metal fuses which is composed of multilayer metal wiring lines and which is formed via an interlayer insulating film in the fuse region on the semiconductor substrate including the trench dummy element isolating region and first dummy element regions,
wherein said plurality of first dummy element regions is formed below all of said plurality of metal fuses.

10. The semiconductor device according to claim 9, wherein each of said plurality of first dummy element regions has the same planar shape as that of the corresponding one of the metal fuses above in the same plane position as that of the metal fuse.

11. The semiconductor device according to claim 9, wherein each of said plurality of first dummy element regions has a smaller planar shape than that of the corresponding one of the metal fuses above in the same plane position as that of the metal fuse.

12. The semiconductor device according to claim 9, wherein each of said plurality of first dummy element regions is formed to extend to below a fuse control circuit wiring line junction connecting with each of said plurality of metal fuses.

13. The semiconductor device according to claim 9, wherein the substrate surface of each of said plurality of first dummy element regions formed below each of said plurality of metal fuses is turned into salicide.

14. The semiconductor device according to claim 9, wherein the substrate surface of each of said plurality of first dummy element regions formed below each of said plurality of metal fuses is not turned into salicide.

15. The semiconductor device according to claim 9, wherein the total of the areas occupied by the first dummy element regions in the fuse region is 20% or more of the area of the fuse region.

16. The semiconductor device according to claim 9, wherein the fuse region is provided in the trench dummy element region, a plurality of second dummy element regions being formed in the trench dummy element region.

17. A semiconductor device with metal fuses comprising:
a semiconductor substrate which has a fuse region;
a trench dummy element isolating region which is formed in the semiconductor substrate;
a plurality of first dummy element regions which is formed in the semiconductor substrate, said plurality of first dummy element regions being enclosed by the trench dummy element isolating region and whose occupancy rate in the fuse region is equal to or larger than a specific value;
a plurality of multilayer metal wiring lines formed via an interlayer insulating film in the fuse region on the semiconductor substrate; and
a plurality of metal fuses which is formed on said plurality of multilayer metal wiring lines and is electrically connected to said plurality of multiplayer metal wiring lines in a one-to-one correspondence,
wherein said plurality of first dummy element regions is formed below all of said plurality of metal fuses.

18. The semiconductor device according to claim 17, wherein each of said plurality of first dummy element regions has the same planar shape as that of the corresponding one of the metal fuses above in the same plane position as that of the metal fuse.

19. The semiconductor device according to claim 17, wherein the total of the areas occupied by the first dummy element regions in the fuse region is 20% or more of the area of the fuse region.

20. The semiconductor device according to claim 17, wherein the fuse region is provided in the trench dummy element region, a plurality of second dummy element regions being formed in the trench dummy element region.
